(19) United States
(12) Patent Application Publication
(10) Pub. No.: US 2025/0287639 A1
(43) Pub. Date: Sep. 11, 2025

(54) SEMICONDUCTOR DEVICE AND SEMICONDUCTOR DEVICE MANUFACTURING METHOD

(71) Applicant: United Semiconductor Japan Co., Ltd., Kuwana-shi (JP)

(72) Inventor: Tetsuo Yoshimura, Yokohama-shi (JP)

(73) Assignee: United Semiconductor Japan Co., Ltd., Kuwana-shi (JP)

(21) Appl. No.: 18/926,378

(22) Filed: Oct. 25, 2024

(30) Foreign Application Priority Data
Mar. 5, 2024 (JP) 2024-032879

(51) Int. Cl. H01L 29/78; H01L 23/367; H01L 23/544; H01L 27/06; H01L 29/66

(52) U.S. Cl. CPC H10D 30/657; H01L 23/367; H01L 23/544; H10D 30/0287; H10D 84/811; H01L 2223/54426

(57) ABSTRACT

A semiconductor device includes an insulating layer having a first surface and a second surface, a first semiconductor layer and a first thermally conductive portion provided in isolation from each other on the first surface side of the insulating layer, and a first element isolation layer defining the first semiconductor layer and covering the first thermally conductive portion. The first thermally conductive portion has a third surface facing the first semiconductor layer in a first direction parallel to the first surface and a fourth surface facing a second direction that is orthogonal to the first direction and being directed away from the first surface. In the semiconductor device, the thickness of a first part of the first element isolation layer located between the first semiconductor layer and the third surface is less than the thickness of the insulating layer between the first surface and the second surface.

### BACKGROUND OF THE INVENTION

### 1. FIELD OF THE INVENTION

The embodiments discussed herein relate to a semiconductor device and a semiconductor device manufacturing method.

### 2. Description of the Prior Art

Semiconductor devices using substrates of silicon on insulator (SOI) structure are known.

For example, there is known a semiconductor device in which an island silicon region where a laterally diffused metal oxide semiconductor (LDMOS) transistor is formed is surrounded by an insulating film including a buried silicon oxide film and a silicon oxide film formed in a groove for element isolation so as to enhance breakdown voltage and element-isolating performance.

For such semiconductor devices, there are known a technique of making a part of a buried silicon oxide film thin, a technique of disposing polycrystalline silicon in the thin part, a technique of filling the interior of a silicon oxide film formed in a groove for element isolation with polycrystalline silicon, and others (see, for example, Japanese Laid-open Patent Publication No. H09-97832).

There is known a semiconductor device in which a substrate of SOI structure is used and a semiconductor layer in an active region where a transistor element is formed and an element isolation layer that is provided around the semiconductor layer to define the semiconductor layer are provided on the insulating layer of the substrate.

In such a semiconductor device, the thermal conductivities of materials used for the insulating layer and element isolation layer surrounding the semiconductor layer are lower than that of a material used for the semiconductor layer in the active region. Therefore, heat generated by self-heating in the semiconductor layer surrounded by the insulating layer and element isolation layer is difficult to dissipate to the outside. As a result, the temperature of the semiconductor layer increases, which may cause performance degradation of the semiconductor device.

In order to improve the heat dissipation, the thickness of the insulating layer provided under the semiconductor layer may be made thinner. In this case, however, there is a risk of lowering the breakdown voltage of the semiconductor device.

In addition, polycrystalline silicon or the like may be provided in the element isolation layer provided around the semiconductor layer. In this case, depending on its placement and connection with other portions, there are risks of reducing the layout flexibility for circuit elements such as electrodes and wiring and lowering the breakdown voltage.

### SUMMARY OF THE INVENTION

According to one aspect, there is provided a semiconductor device, including: an insulating layer having a first surface on a first side thereof and a second surface on a second side thereof opposite to the first side; a first semiconductor layer provided on the first side of the insulating layer; a first thermally conductive portion provided in isolation from the first semiconductor layer on the first side of the insulating layer, the first thermally conductive portion having a third surface and a fourth surface, the third surface facing the first semiconductor layer in a first direction parallel to the first surface, the fourth surface facing a second direction that is orthogonal to the first direction and is directed away from the first surface; and a first element isolation layer provided on the first side of the insulating layer to define the first semiconductor layer and to cover the third surface and the fourth surface of the first thermally conductive portion, wherein a thickness of a first part of the first element isolation layer located between the first semiconductor layer and the third surface is less than a thickness of the insulating layer between the first surface and the second surface.

The object and advantages of the invention will be realized and attained by means of the elements and combinations particularly pointed out in the claims.

It is to be understood that both the foregoing general description and the following detailed description are exemplary and explanatory and are not restrictive of the invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a first view for describing an example of a semiconductor device according to a first embodiment;

FIG. 2 is a second view for describing the example of the semiconductor device according to the first embodiment;

FIG. 3 is a view for describing an example of a semiconductor device according to a second embodiment;

FIG. 4 is a view for describing an example of a semiconductor device according to a third embodiment;

FIG. 5 is a view for describing an example of a semiconductor device according to a fourth embodiment;

FIG. 6 is a first view for describing an example of a semiconductor device manufacturing method according to a fifth embodiment;

FIG. 7 is a second view for describing the example of the semiconductor device manufacturing method according to the fifth embodiment;

FIG. 8 is a third view for describing the example of the semiconductor device manufacturing method according to the fifth embodiment;

FIG. 9 is a fourth view for describing the example of the semiconductor device manufacturing method according to the fifth embodiment;

FIG. 10 is a fifth view for describing the example of the semiconductor device manufacturing method according to the fifth embodiment;

FIG. 11 is a sixth view for describing the example of the semiconductor device manufacturing method according to the fifth embodiment;

FIG. 12 is a seventh view for describing the example of the semiconductor device manufacturing method according to the fifth embodiment;

FIG. 13 is an eighth view for describing the example of the semiconductor device manufacturing method according to the fifth embodiment; and

FIG. 14 is a ninth view for describing the example of the semiconductor device manufacturing method according to the fifth embodiment.

### DETAILED DESCRIPTION

### First Embodiment

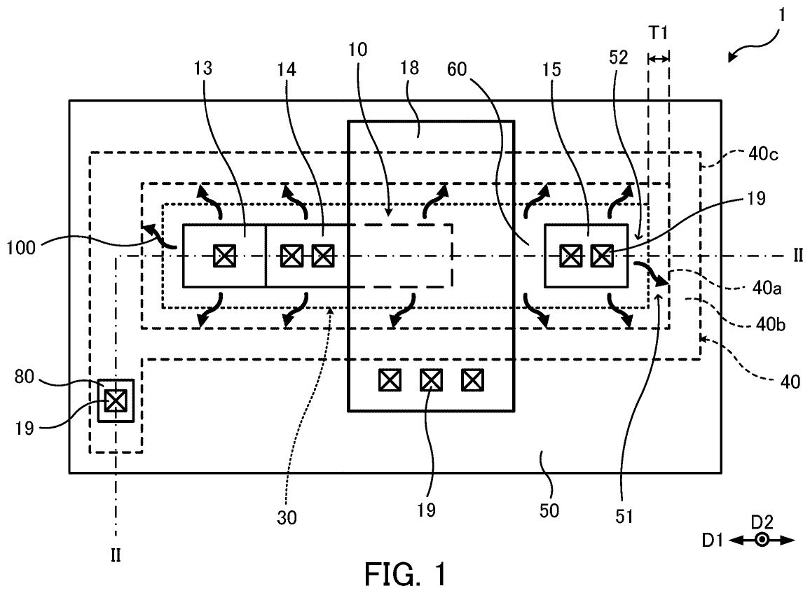

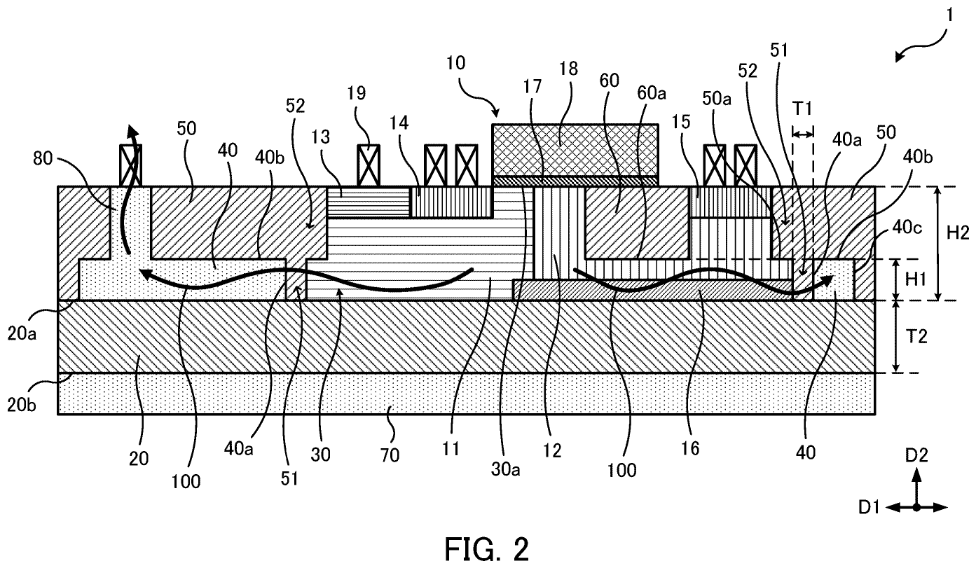

FIGS. 1 and 2 are views for describing an example of a semiconductor device according to a first embodiment. FIG. 1 is a schematic plan view of a main part of the example semiconductor device. FIG. 2 is a schematic sectional view of the main part of the example semiconductor device, taken along a line II-II of FIG. 1.

In FIGS. 1 and 2, an example of heat 100 generated in the semiconductor device 1 and its propagation is schematically represented by thick arrows, for convenience.

The semiconductor device 1 illustrated in FIGS. 1 and 2 is an example of a semiconductor device having a transistor element formed using a substrate (referred to as an “SOI substrate”) of SOI structure. As an example, the illustrated semiconductor device 1 has a laterally diffused metal oxide semiconductor (LDMOS) transistor 10, which is one type of high breakdown voltage transistor, as a transistor element.

As illustrated in FIGS. 1 and 2, the semiconductor device 1 includes an insulating layer 20, a first semiconductor layer 30, a first thermally conductive portion 40, and a first element isolation layer 50.

The insulating layer 20 has a first surface 20a (upper surface) and a second surface 20b (lower surface) opposite to the first surface 20a, as illustrated in FIG. 2. A variety of insulating materials, for example, silicon oxide (SiO₂ or SiO), are used for the insulating layer 20. The insulating layer 20 is a buried oxide (BOX) layer in the SOI substrate.

The first semiconductor layer 30 is provided on the first surface 20a side of the insulating layer 20, as illustrated in FIG. 2. For example, the first semiconductor layer 30 is provided in contact with the first surface 20a of the insulating layer 20, as illustrated in FIG. 2. A variety of semiconductor materials, for example, silicon (Si), are used for the first semiconductor layer 30. For example, the first semiconductor layer 30 is formed by patterning a predetermined semiconductor material formed on the first surface 20a side of the insulating layer 20 through etching.

The first element isolation layer 50 is provided on the first surface 20a side of the insulating layer 20, as illustrated in FIG. 2. The first element isolation layer 50 is provided to define the first semiconductor layer 30, as illustrated in FIGS. 1 and 2. A variety of insulating materials, for example, silicon oxide, are used for the first element isolation layer 50. For example, the first element isolation layer 50 is formed with shallow trench isolation (STI), which fills the area around the first semiconductor layer 30, formed by patterning through etching, with a predetermined insulating material.

The LDMOS transistor 10 as illustrated in FIGS. 1 and 2 is formed on the first semiconductor layer 30 defined by the first element isolation layer 50. The first semiconductor layer 30 is an active region or a device region where the LDMOS transistor 10 is formed in the semiconductor device 1.

The LDMOS transistor 10 includes a body region 11 of a first conductivity type and a drift region 12 of a second conductivity type adjacent to the body region 11, as illustrated in FIG. 2. The first conductivity type and the second conductivity type are opposite to each other. For example, the first conductivity type is p-type, and the second conductivity type is n-type.

A body contact region 13 of the first conductivity type and a source region 14 of the second conductivity type are provided at the surface layer of the body region 11, as illustrated in FIGS. 1 and 2. A drain region 15 of the second conductivity type is provided at the surface layer of the drift region 12, as illustrated in FIGS. 1 and 2. The source region 14 is isolated from the drift region 12 by the body region 11. A deep well layer 16 of the second conductivity type is provided at the bottom layers of the body region 11 and drift region 12 located on the insulating layer 20 side, as illustrated in FIG. 2.

As illustrated in FIGS. 1 and 2, a gate electrode 18 is provided on the side of the body region 11 and drift region 12 opposite to the insulating layer 20, that is, on the body region 11 and drift region 12 with a gate insulating film 17 interposed therebetween. A variety of insulating materials, for example, silicon oxide, are used for the gate insulating film 17, and a variety of electrically conductive materials, for example, polysilicon, are used for the gate electrode 18.

As illustrated in FIGS. 1 and 2, contacts 19 are connected to the body contact region 13, source region 14, drain region 15, and gate electrode 18 (contacts connected to the gate electrode 18 are not illustrated). A variety of electrically conductive materials, for example, tungsten (W), are used for the contacts 19. Although not illustrated here, the contacts 19 are electrically connected to a wiring layer of multilayer wiring structure that is provided to cover the LDMOS transistor 10.

In this connection, a metal silicide layer (not illustrated) may be provided on the surface layers of the body contact region 13, source region 14, drain region 15, and gate electrode 18, and the contacts 19 may be connected to the metal silicide layer.

A second element isolation layer 60 may be provided in the first semiconductor layer 30 in order to extend the drift distance of carriers in the drift region 12 between the gate electrode 18 and the drain region 15 and to thereby increase the breakdown voltage. The second element isolation layer 60 may be continuous with the first element isolation layer 50. The second element isolation layer 60 may be formed as a part of the first element isolation layer 50, that is, a part of the first element isolation layer 50 extending from just below the gate electrode 18 to reach the drain region 15.

A second semiconductor layer 70 serving as a support substrate may be provided on the second surface 20b side of the insulating layer 20, as illustrated in FIG. 2. A variety of semiconductor materials, for example, silicon, are used for the second semiconductor layer 70. For example, the second semiconductor layer 70 may be connected to the earth potential.

A laminate of the insulating layer 20 and first semiconductor layer 30 or a laminate of the insulating layer 20, first semiconductor layer 30, and second semiconductor layer 70 corresponds to the SOI substrate. In the SOI substrate, the insulating layer 20 is referred to as a BOX layer. The BOX layer is referred to as a buried insulating layer, an embedded insulating layer, or another.

For example, the LDMOS transistor 10 may be configured as an n-type LDMOS transistor, in which the above first conductivity type is p-type and the above second conductivity type is n-type. Alternatively, the LDMOS transistor 10 may be configured as a p-type LDMOS transistor, in which the above first conductivity type is n-type and the above second conductivity type is p-type.

The semiconductor device 1 is provided with the first thermally conductive portion 40. The first thermally conductive portion 40 is provided on the first surface 20a side of the insulating layer 20, as illustrated in FIG. 2. The first thermally conductive portion 40 is provided in isolation from the first semiconductor layer 30, as illustrated in FIGS. 1 and 2. As an example, the first thermally conductive portion 40 is provided to surround the entire periphery of the first semiconductor layer 30 where the LDMOS transistor 10 is formed, as illustrated in FIGS. 1 and 2.

For example, the first thermally conductive portion 40 is provided in contact with the first surface 20a of the insulating layer 20 and in isolation from the first semiconductor layer 30, as illustrated in FIG. 2. For example, the first thermally conductive portion 40 and the first semiconductor layer 30 are provided such that their surfaces facing toward the insulating layer 20 are in the same plane parallel to the first surface 20a and are, in this example, flush with the first surface 20a, as illustrated in FIG. 2.

A variety of materials with thermal conductivity are used for the first thermally conductive portion 40. For example, a semiconductor material such as silicon is used for the first thermally conductive portion 40. As an example, the same semiconductor material as used for the first semiconductor layer 30 is used for the first thermally conductive portion 40. For example, silicon is used for both the first thermally conductive portion 40 and the first semiconductor layer 30. For example, the first thermally conductive portion 40 is formed, together with the first semiconductor layer 30 in the device region, by patterning through etching.

As illustrated in FIGS. 1 and 2, the first thermally conductive portion 40 has a third surface 40a (side surface) and a fourth surface 40b (upper surface). The third surface 40a faces the first semiconductor layer 30 in a first direction D1 parallel to the first surface 20a of the insulating layer 20, and the fourth surface 40b faces a second direction D2 that is orthogonal to the first direction D1 and is directed away from the first surface 20a.

As illustrated in FIGS. 1 and 2, the third surface 40a of the first thermally conductive portion 40 is provided at a position a predetermined distance apart from the first semiconductor layer 30. The predetermined distance here corresponds to the thickness T1 of a first part 51 of the first element isolation layer 50 that will be described later. As illustrated in FIG. 2, the height H1 of the fourth surface 40b of the first thermally conductive portion 40 from the first surface 20a of the insulating layer 20 is lower than the height H2, from the first surface 20a of the insulating layer 20, of a fifth surface 30a (upper surface) of the first semiconductor layer 30 located opposite to the insulating layer 20. In this connection, the fifth surface 30a of the first semiconductor layer 30 is not covered with the first element isolation layer 50 or second element isolation layer 60 but is exposed therefrom.

As illustrated in FIGS. 1 and 2, the first element isolation layer 50 is provided to cover the third surface 40a and fourth surface 40b of the first thermally conductive portion 40.

In this connection, the first thermally conductive portion 40 has, in addition to the third surface 40a, a surface 40c (side surface) opposite to the third surface 40a as surfaces facing the first direction D1 parallel to the first surface 20a of the insulating layer 20, as illustrated in FIGS. 1 and 2. The first element isolation layer 50 is provided to cover the surface 40c as well as the third surface 40a and fourth surface 40b of the first thermally conductive portion 40. It may be said that the first thermally conductive portion 40 is provided in the first element isolation layer 50.

In the semiconductor device 1, the thickness T1 of the first part 51 of the first element isolation layer 50 located between the first semiconductor layer 30 and the third surface 40a of the first thermally conductive portion 40 is less than the thickness T2 of the insulating layer 20 between the first surface 20a and the second surface 20b thereof, as illustrated in FIG. 2. In the semiconductor device 1, the distance between the first semiconductor layer 30 and the first thermally conductive portion 40 (the third surface 40a thereof) provided in isolation from the first semiconductor layer 30, i.e., the thickness T1 of the first part 51 of the first element isolation layer 50 located between the first semiconductor layer 30 and the first thermally conductive portion 40 is adjusted so as to obtain the thickness relationship of T1<T2.

A second thermally conductive portion 80 that is continuous with the first thermally conductive portion 40 may be provided in the first element isolation layer 50, as illustrated in FIGS. 1 and 2. For example, the second thermally conductive portion 80 is provided to extend from the fourth surface 40b of the first thermally conductive portion 40 in the second direction D2 until the second thermally conductive portion 80 partly extends outside the first element isolation layer 50. As illustrated in FIGS. 1 and 2, a contact 19 formed of tungsten or the like may be connected to the part of the second thermally conductive portion 80 extending outside the first element isolation layer 50.

In the semiconductor device 1, the first thermally conductive portion 40, or the first thermally conductive portion 40 and second thermally conductive portion 80, when connected to the first thermally conductive portion 40, are provided so that they are electrically floating, i.e., they are electrically isolated from the LDMOS transistor 10 and other circuit elements of the semiconductor device 1.

In the semiconductor device 1 using the SOI substrate, the first semiconductor layer 30 in the device region where the LDMOS transistor 10 is formed is isolated from its surroundings by the insulating layer 20 and first element isolation layer 50. This secures the breakdown voltages between the LDMOS transistor 10 and the second semiconductor layer 70 provided on the second surface 20b side of the insulating layer 20 and between the LDMOS transistor 10 and another transistor or another that is provided with the first element isolation layer 50 interposed therebetween.

In the semiconductor device 1 configured as above, the LDMOS transistor 10 formed on the first semiconductor layer 30 in the device region generates heat during its operation. This heat generation is referred to as self-heating.

In the above-described semiconductor device 1, the thermal conductivities of the materials used for the insulating layer 20 and first element isolation layer 50 surrounding the first semiconductor layer 30 in the device region may be lower than that of the material used for the first semiconductor layer 30. For example, in the case where silicon is used for the first semiconductor layer 30 and silicon oxide is used for the insulating layer 20 and first element isolation layer 50, silicon has a thermal conductivity of 168 W/(m·K), and silicon oxide has a thermal conductivity of 1.38 W/(m·K).

The following describes a hypothetical case where the first thermally conductive portion 40 (and the second thermally conductive portion 80 connected thereto) as described above is not provided in the semiconductor device 1. Even in this case, the first semiconductor layer 30 on which the LDMOS transistor 10 is formed is isolated from its surroundings by the insulating layer 20 and first element isolation layer 50, which secures the breakdown voltage, as described above. However, the first semiconductor layer 30 is surrounded by the insulating layer 20 and first element isolation layer 50 that each has a lower thermal conductivity than the first semiconductor layer 30, and therefore the heat generated during the operation of the LDMOS transistor 10 is difficult to be dissipated outside the first semiconductor layer 30. If the heat dissipation is suppressed and the temperature of the first semiconductor layer 30 therefore increases, the driving capability of the LDMOS transistor 10 is reduced accordingly. If the thickness T2 of the insulating layer 20 is made thin, the heat dissipation from the first semiconductor layer 30 through the insulating layer 20 would increase. However, the reduction in the thickness T2 of the insulating layer 20 causes a decrease in the breakdown voltage. Especially, in the case where the second semiconductor layer 70 is provided on the side of the insulating layer 20 opposite to the first semiconductor layer 30 and the second semiconductor layer 70 is at the earth potential, the breakdown voltage is more likely to decrease. If the thickness T2 of the insulating layer 20 is made thick, such a decrease in the breakdown voltage would be avoided, but the heat dissipation from the first semiconductor layer 30 through the insulating layer 20 will decrease.

By contrast, in the above-described semiconductor device 1, the first thermally conductive portion 40 is provided apart from the first semiconductor layer 30 in the device region where the LDMOS transistor 10 is formed, in the first element isolation layer 50, as illustrated in FIGS. 1 and 2. In addition, the second thermally conductive portion 80 may be further provided which is continuous with the first thermally conductive portion 40 in the first element isolation layer 50 and partly extends outside the first element isolation layer 50. The first element isolation layer 50 is provided so as to cover the first thermally conductive portion 40, that is, to cover the third surface 40a and fourth surface 40b (and surface 40c) thereof. The first thermally conductive portion 40 and first element isolation layer 50 are provided such that the thickness T1 of the first part 51 of the first element isolation layer 50 located between the third surface 40a of the first thermally conductive portion 40 and the first semiconductor layer 30 is less than the thickness T2 of the insulating layer 20.

As a result, in the semiconductor device 1, the breakdown voltage is secured by the relatively thick insulating layer 20 and first element isolation layer 50 that surround the first semiconductor layer 30. In addition, in the semiconductor device 1, the heat 100 generated by the self-heating of the LDMOS transistor 10 formed on the first semiconductor layer 30 is propagated through the relatively thin first part 51 to the first thermally conductive portion 40, as illustrated in FIGS. 1 and 2.

In the semiconductor device 1, even while the relatively thick insulating layer 20 reduces the propagation and dissipation of the heat 100 from the first surface 20a to the second surface 20b, the heat 100 is propagated to the first thermally conductive portion 40 through the relatively thin first part 51. The heat 100 propagated to the first thermally conductive portion 40 is propagated or diffused, or is dispersed inside the first thermally conductive portion 40. This suppresses the increase in the temperature of the first semiconductor layer 30 caused by the self-heating of the LDMOS transistor 10, and accordingly suppresses the reduction in the driving capability of the LDMOS transistor 10 caused by the temperature increase.

In the semiconductor device 1, the decrease in the breakdown voltage is suppressed by the relatively thick insulating layer 20. Even in the case where the second semiconductor layer 70 is provided on the second surface 20b side of the insulating layer 20 and is at the earth potential, the decrease in the breakdown voltage is suppressed. Furthermore, in the semiconductor device 1, the first thermally conductive portion 40, through which the heat 100 from the first semiconductor layer 30 is propagated, is electrically floating, which suppresses the decrease in the breakdown voltage effectively.

In the semiconductor device 1, the first thermally conductive portion 40 and the second thermally conductive portion 80 that is continuous with the first thermally conductive portion 40 are further provided. Therefore, the heat 100 propagated from the first semiconductor layer 30 to the first thermally conductive portion 40 is further propagated or diffused, or is dispersed to the second thermally conductive portion 80. This effectively suppresses the increase in the temperature of the first semiconductor layer 30 caused by the self-heating of the LDMOS transistor 10. In addition, the second thermally conductive portion 80 has a part extending outside the first element isolation layer 50, so that the heat 100 is dissipated from the part extending outside the first element isolation layer 50. This further effectively suppresses the increase in the temperature of the first semiconductor layer 30 caused by the self-heating of the LDMOS transistor 10. In addition, the second thermally conductive portion 80, as well as the first thermally conductive portion 40, is formed in an electrically floating state, which suppresses the decrease in the breakdown voltage.

In the semiconductor device 1, a region where the second thermally conductive portion 80, which is continuous with the first thermally conductive portion 40, is provided may be called a heat sink region.

In the semiconductor device 1, as illustrated in FIG. 1 (and FIG. 2), the gate electrode 18 of the LDMOS transistor 10 overlaps the first semiconductor layer 30 in plan view. In the case where the second element isolation layer 60 is provided, the gate electrode 18 is provided to overlap the first semiconductor layer 30 and second element isolation layer 60 in plan view. Furthermore, the gate electrode 18 may be provided to overlap the first element isolation layer 50, and the first thermally conductive portion 40 covered with the first element isolation layer 50 in plan view, as illustrated in FIG. 1. In the semiconductor device 1, the first element isolation layer 50 is provided to cover the first thermally conductive portion 40. This avoids a reduction in the layout flexibility for the gate electrode 18 in the case where the gate electrode 18 is provided (or routed) on the first element isolation layer 50. In other words, restrictions on the layout (or routing) of the gate electrode 18 due to the presence of the first thermally conductive portion 40 are eased.

The case of providing the gate electrode 18 has been described as an example. Alternatively, the semiconductor device 1 may be provided with a variety of circuit elements, for example, an electrode or a part thereof, a wiring or a part thereof, a resistor or a part thereof, a capacitor or a part thereof, and an inductor or a part thereof on the first element isolation layer 50. Such cases suppress the reduction in the layout flexibility for the variety of circuit elements as well. That is, the semiconductor device 1 may have a layout in which such a circuit element is provided to overlap the first element isolation layer 50 and the first thermally conductive portion 40 covered with the first element isolation layer 50 in plan view.

With the above-described configuration, the semiconductor device 1 is achieved, which has high layout flexibility for circuit elements and suppresses performance degradation caused by the self-heating and a decrease in the breakdown voltage.

In addition, with regard to the semiconductor device 1 configured as described above, the first thermally conductive portion 40 is provided in contact with the first surface 20a of the insulating layer 20, for example, as illustrated in FIG. 2. In the case where depressions are formed in the first surface 20a of the insulating layer 20, the first thermally conductive portion 40 may be provided in contact with the inner surfaces of the depressions in the first surface 20a.

Furthermore, with respect to the semiconductor device 1, the first semiconductor layer 30 is provided in contact with the first surface 20a of the insulating layer 20, for example, as illustrated in FIG. 2. In the case where depressions are provided in the first surface 20a of the insulating layer 20, the first semiconductor layer 30 may be provided in contact with the inner surfaces of the depressions in the first surface 20a.

In addition, with respect to the semiconductor device 1, the first thermally conductive portion 40 and the first semiconductor layer 30 do not necessarily have to be in contact with the first surface 20a of the insulating layer 20, and another layer (an insulating layer or another) may be interposed between them. The first thermally conductive portion 40 and the first semiconductor layer 30 may be provided such that their surfaces facing toward the insulating layer 20 are located in the same plane parallel to the first surface 20a, regardless of whether or not another layer is interposed between each of the first thermally conductive portion 40 and first semiconductor layer 30 and the first surface 20a of the insulating layer 20.

Further, with respect to the semiconductor device 1, the first element isolation layer 50 may be provided to have a second part 52 extending further toward the first semiconductor layer 30 than the first part 51, for example, as illustrated in FIGS. 1 and 2. The second part 52 is a part that is provided on the side of the first part 51 opposite to the insulating layer 20 and is continuous with the first part 51. The second part 52 has a sixth surface 50a (lower surface) that faces toward the insulating layer 20 and is located apart from the first surface 20a of the insulating layer 20, as illustrated in FIG. 2. A part of the first semiconductor layer 30 is interposed between the sixth surface 50a and the first surface 20a and is in contact with the sixth surface 50a. The first element isolation layer 50 may be provided such that the height of the sixth surface 50a from the first surface 20a, that is, the height, from the first surface 20a, of the part of the first semiconductor layer 30 interposed between the sixth surface 50a and the first surface 20a is equal to the height H1 of the fourth surface 40b of the first thermally conductive portion 40 from the first surface 20a.

Still further, with respect to the semiconductor device 1, in the case where the second element isolation layer 60 as illustrated in FIGS. 1 and 2 is provided in the first semiconductor layer 30, the second element isolation layer 60 is provided to have a seventh surface 60a (lower surface) that faces toward the insulating layer 20 and is located apart from the first surface 20a of the insulating layer 20, as illustrated in FIG. 2. A part of the first semiconductor layer 30 is interposed between the seventh surface 60a and the first surface 20a and is in contact with the seventh surface 60a. The second element isolation layer 60 may be provided such that the height of the seventh surface 60a from the first surface 20a, that is, the height, from the first surface 20a, of the part of the first semiconductor layer 30 interposed between the seventh surface 60a and the first surface 20a is equal to the height H1 of the fourth surface 40b of the first thermally conductive portion 40 from the first surface 20a.

Still further, with respect to the semiconductor device 1, the first surface 20a and second surface 20b of the insulating layer 20 do not necessarily have to be flat surfaces, but may be surfaces with concave portions, convex portions, concave and convex portions, or the like.

Still further, with respect to the semiconductor device 1, the third surface 40a of the first thermally conductive portion 40 does not necessarily have to be a flat surface perpendicular to the first surface 20a of the insulating layer 20, but may be a surface with concave portions, convex portions, concave and convex portions, or the like. Even in the case where the third surface 40a is not a flat surface perpendicular to the first surface 20a, the heat 100 is able to be propagated through the first part 51 of the first element isolation layer 50 located between the first semiconductor layer 30 and the third surface 40a, which makes it possible to suppress an increase in the temperature of the first semiconductor layer 30.

Still further, with respect to the semiconductor device 1, the fourth surface 40b of the first thermally conductive portion 40 does not necessarily have to be a flat surface parallel to the first surface 20a of the insulating layer 20, but may be a surface with concave portions, convex portions, concave and convex portions, or the like. Even in the case where the fourth surface 40b is not a flat surface parallel to the first surface 20a, it is possible to cover the first thermally conductive portion 40 with the first element isolation layer 50 and to dispose a variety of circuit elements on the first element isolation layer 50 covering the first thermally conductive portion 40.

Still further, with respect to the semiconductor device 1, the fifth surface 30a of the first semiconductor layer 30 does not necessarily have to be a flat surface parallel to the first surface 20a of the insulating layer 20, but may be a surface with concave portions, convex portions, concave and convex portions, or the like.

Still further, with respect to the semiconductor device 1, the sixth surface 50a of the second part 52 of the first element isolation layer 50 (or a partial surface of the first semiconductor layer 30 in contact therewith) does not necessarily have to be a flat surface parallel to the first surface 20a of the insulating layer 20, but may be a surface with concave portions, convex portions, concave and convex portions, or the like.

Still further, with respect to the semiconductor device 1, the seventh surface 60a of the second element isolation layer 60 (or a partial surface of the first semiconductor layer 30 in contact therewith) does not necessarily have to be a flat surface parallel to the first surface 20a of the insulating layer 20, but may be a surface with concave portions, convex portions, concave and convex portions, or the like.

In FIG. 2, the insulating layer 20 is illustrated thinner than the first semiconductor layer 30 for convenience. However, the thickness relationship between the first semiconductor layer 30 and the insulating layer 20 is not limited to the illustrated one.

Although not illustrated here, the semiconductor device 1 may be further provided with a region where an alignment mark, which is used in a process of manufacturing the semiconductor device 1, is formed. The details of the process of manufacturing the semiconductor device 1 will be described in detail later (fifth embodiment). In the semiconductor device 1, the region where such an alignment mark is formed may be called an alignment mark region.

### Second Embodiment

The first embodiment has described, as an example, the semiconductor device 1 that includes the LDMOS transistor 10, which is one type of high breakdown voltage transistor, as a transistor element. However, the type of the transistor element is not limited thereto.

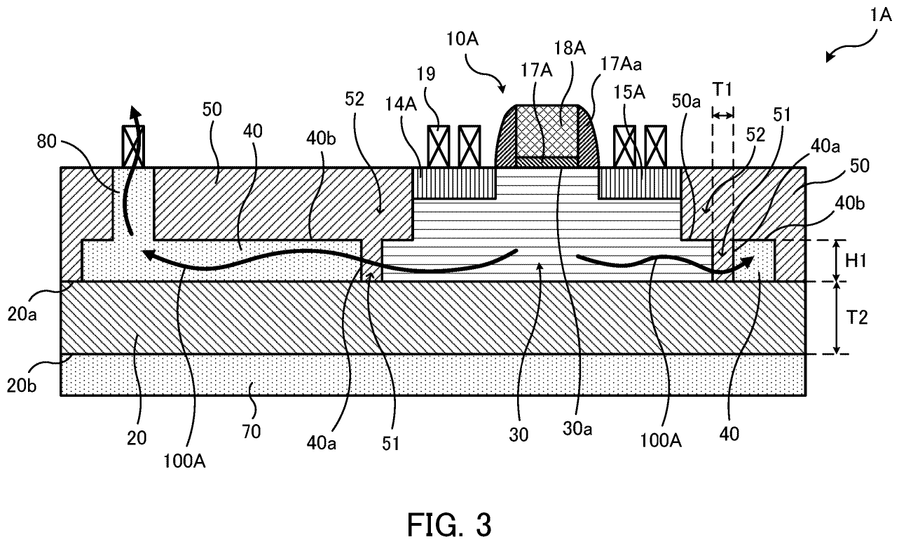

FIG. 3 illustrates an example of a semiconductor device according to a second embodiment. FIG. 3 is a schematic sectional view of a main part of the example semiconductor device.

In FIG. 3, an example of heat 100A generated in the semiconductor device 1A and its propagation is schematically represented by thick arrows, for convenience.

The semiconductor device 1A illustrated in FIG. 3 differs from the semiconductor device 1 described above in the first embodiment in that the semiconductor device 1A is configured to have a MOS transistor 10A on a first semiconductor layer 30 in the device region defined by a first element isolation layer 50. The remaining configuration of the semiconductor device 1A is the same as that of the above-described semiconductor device 1.

The MOS transistor 10A includes a source region 14A, a drain region 15A, a gate insulating film 17A, a gate electrode 18A, and a sidewall insulating film 17Aa. The source region 14A and the drain region 15A are provided in isolation from each other in the first semiconductor layer 30. The gate electrode 18A is provided on the first semiconductor layer 30 between the source region 14A and the drain region 15A, with the gate insulating film 17A interposed therebetween, and the sidewall insulating film 17Aa is provided on the sidewall of the gate electrode 18A. Contacts 19 are connected to the source region 14A, drain region 15A, and gate electrode 18A (contacts connected to the gate electrode 18A are not illustrated).

As in this semiconductor device 1A, a transistor element configured like the MOS transistor 10A, which is not limited to high voltage applications, may be formed in the device region.

The MOS transistor 10A generates heat during its operation. In the semiconductor device 1A, the heat 100A generated by the MOS transistor 10A formed on the first semiconductor layer 30 is propagated to a first thermally conductive portion 40 through a first part 51 of the first element isolation layer 50, which has a thickness T1 less than the thickness T2 of the insulating layer 20. The heat 100A propagated to the first thermally conductive portion 40 is further propagated to a second thermally conductive portion 80 that is continuous with the first thermally conductive portion 40, and is dissipated through a part of the second thermally conductive portion 80 extending outside the first element isolation layer 50 or a contact 19 connected to the extending part. As a result, an increase in the temperature of the first semiconductor layer 30 due to the self-heating of the MOS transistor 10A is suppressed, and a reduction in the driving capability of the MOS transistor 10A caused by the temperature increase is suppressed accordingly.

In addition, the semiconductor device 1A is also configured so that the first semiconductor layer 30, on which the MOS transistor 10A is formed, is surrounded by the insulating layer 20 and the first element isolation layer 50, which suppresses a decrease in the breakdown voltage. Furthermore, the semiconductor device 1A is also configured so that the first thermally conductive portion 40 is covered with the first element isolation layer 50, which suppresses a reduction in the layout flexibility for a variety of circuit elements to be provided on the first element isolation layer 50, including the gate electrode 18A.

This second embodiment also achieves the semiconductor device 1A that has high layout flexibility for circuit elements and suppresses performance degradation caused by the self-heating and a decrease in the breakdown voltage.

In FIG. 3, the insulating layer 20 is illustrated thinner than the first semiconductor layer 30 for convenience. However, the thickness relationship between the first semiconductor layer 30 and the insulating layer 20 is not limited to the illustrated one.

### Third Embodiment

The first embodiment has described, as an example, the semiconductor device 1 that includes the first thermally conductive portion 40 surrounding the entire periphery of the first semiconductor layer 30 in plan view. However, the location and shape of the first thermally conductive portion 40 is not limited thereto.

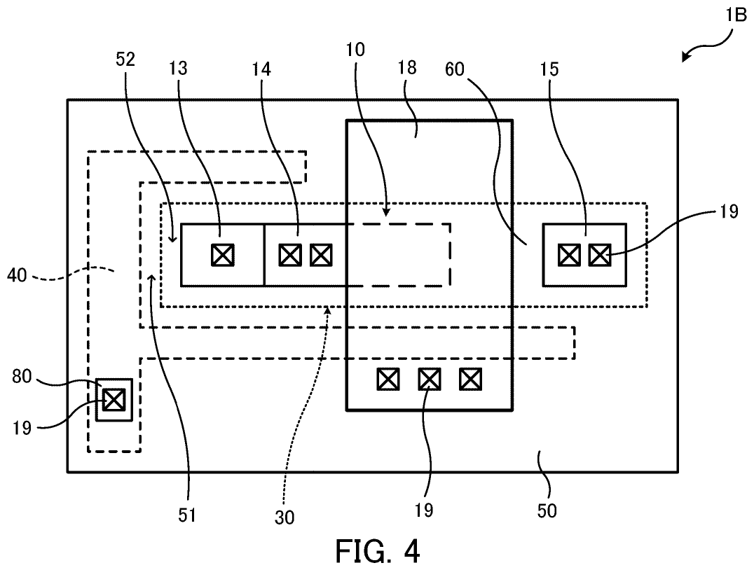

FIG. 4 illustrates an example of a semiconductor device according to a third embodiment. FIG. 4 is a schematic plan view of a main part of the example semiconductor device.

The semiconductor device 1B illustrated in FIG. 4 differs from the semiconductor device 1 described above in the first embodiment in that the semiconductor device 1B is configured so that a first thermally conductive portion 40 is provided in a first element isolation layer 50 to surround only a part of the entire periphery of a first semiconductor layer 30 on which an LDMOS transistor 10 is formed. The remaining configuration of the semiconductor device 1B is the same as that of the above-described semiconductor device 1.

As in this semiconductor device 1B, the first thermally conductive portion 40 does not necessarily have to surround the entire periphery of the first semiconductor layer 30.

In the semiconductor device 1B as well, the heat generated by the LDMOS transistor 10 is propagated to the first thermally conductive portion 40 through a relatively thin first part 51 of the first element isolation layer 50. The heat propagated to the first thermally conductive portion 40 is further propagated to a second thermally conductive portion 80 that is continuous with the first thermally conductive portion 40, and is dissipated through a part of the second thermally conductive portion 80 extending outside the first element isolation layer 50 or a contact 19 connected to the extending part. As a result, an increase in the temperature of the first semiconductor layer 30 due to the self-heating of the LDMOS transistor 10 is suppressed, and a reduction in the driving capability of the LDMOS transistor 10 caused by the temperature increase is suppressed accordingly.

Furthermore, as to the layout flexibility for a variety of circuit elements and the breakdown voltage, the semiconductor device 1B has the same effects as the above-described semiconductor device 1.

That is, this third embodiment also achieves the semiconductor device 1B that has high layout flexibility for circuit elements and suppresses performance degradation caused by the self-heating and a decrease in the breakdown voltage.

### Fourth Embodiment

The first embodiment has described, as an example, the semiconductor device 1 that has one LDMOS transistor 10 as a transistor element. However, the semiconductor device 1 may be configured so that a plurality of transistor elements are integrated.

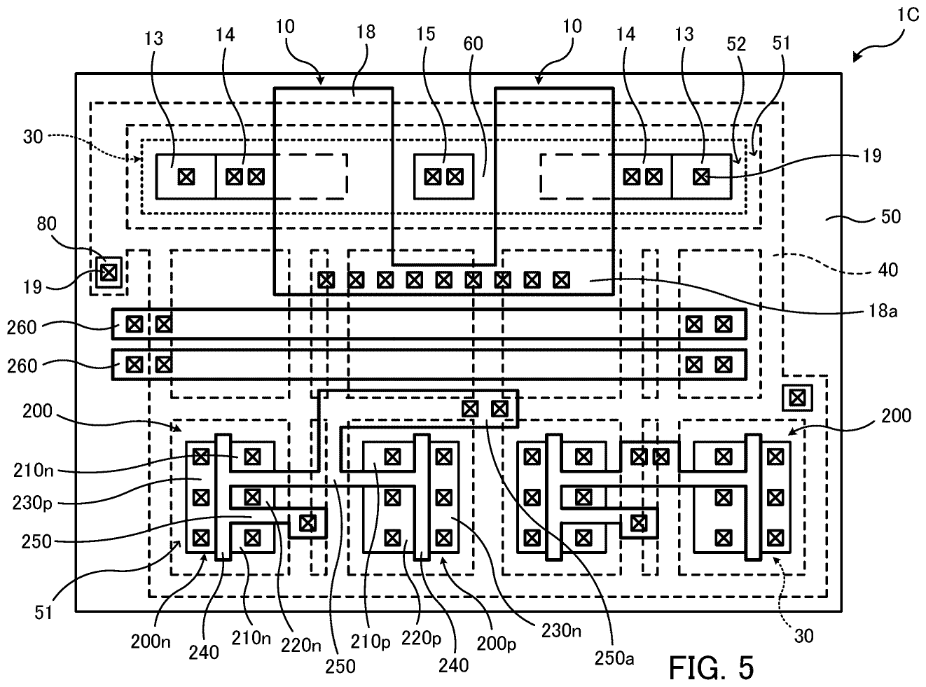

FIG. 5 is a view for describing an example of a semiconductor device according to a fourth embodiment. FIG. 5 is a schematic plan view of a main part of the example semiconductor device.

The semiconductor device 1C illustrated in FIG. 5 includes a first semiconductor layer 30 that is provided on an insulating layer 20 of SOI substrate in the device region defined by a first element isolation layer 50, as in the case described above. As an example, two LDMOS transistors 10 that are connected in parallel and share a drift region 12 (not illustrated) and a drain region 15, two sets of complementary metal oxide semiconductor (CMOS) transistors 200, and two wirings 260 are provided in the device region.

Each CMOS transistor 200 includes an n-channel MOS (nMOS) transistor 200n and a p-channel MOS (pMOS) transistor 200p.

The nMOS transistor 200n has an n-type source region 210n, an n-type drain region 220n adjacent to the n-type source region 210n, and a p-type body region (p-type well region) 230p facing the n-type source region 210n and n-type drain region 220n. The nMOS transistor 200n also has a separate gate 240 located between the n-type source region 210n and n-type drain region 220n on one side and the p-type body region 230p on the other, and a gate electrode 250 located between the n-type source region 210n and the n-type drain region 220n. Contacts 19 are connected to the n-type source region 210n, n-type drain region 220n, and p-type body region 230p.

The pMOS transistor 200p has a p-type source region 210p, a p-type drain region 220p adjacent to the p-type source region 210p, and an n-type body region (n-type well region) 230n facing the p-type source region 210p and p-type drain region 220p. The pMOS transistor 200p also has a separate gate 240 located between the p-type source region 210p and p-type drain region 220p on one side and the n-type body region 230n on the other, and a gate electrode 250 located between the p-type source region 210p and the p-type drain region 220p. Contacts 19 are connected to the p-type source region 210p, the p-type drain region 220p, and the n-type body region 230n.

Each transistor element of the LDMOS transistor 10, nMOS transistor 200n, and pMOS transistor 200p, which are configured as above, is formed in the corresponding device region defined by the first element isolation layer 50.

In the semiconductor device 1C, a first thermally conductive portion 40 is provided to surround the two LDMOS transistors 10 in plan view. In the semiconductor device 1C, first thermally conductive portions 40 are provided to surround the nMOS transistors 200n and pMOS transistors 200p of the CMOS transistors 200, respectively, in plan view. In addition, the first thermally conductive portions 40 surrounding the transistor elements of the LDMOS transistor 10, nMOS transistor 200n, and pMOS transistor 200p are connected by an additional first thermally conductive portion 40. The first element isolation layer 50 is provided to cover the first thermally conductive portions 40 provided as above. Second thermally conductive portions 80 are connected at predetermined positions, in this example, two positions to the first thermally conductive portions 40, and a contact 19 is connected to a part of each second thermally conductive portion 80 extending outside the first element isolation layer 50.

The gate electrodes 18 of the LDMOS transistors 10, as well as wirings 18a drawn from the gate electrodes 18 and contacts 19 connected thereto, are provided on the first element isolation layer 50 covering the first thermally conductive portions 40. In addition, the separate gates 240 and gate electrodes 250 of the CMOS transistors 200, as well as wirings 250a drawn from the gate electrodes 250 and contacts 19 connected thereto, are provided on the first element isolation layer 50. Furthermore, a conductor pattern of a predetermined shape, in this example, two straight wirings 260 and contacts 19 connected thereto are provided on the first element isolation layer 50. For example, the wirings 260, which form a conductor pattern, may be formed of the same material as the gate electrodes 18, the wirings 18a drawn from the gate electrodes 18, the separate gates 240 and gate electrodes 250, and the wirings 250a drawn from the gate electrodes 250. The wirings 260 may be used not only as mere wirings but also as, for example, resistors. For example, the gate electrodes 18, the wirings 18a drawn from the gate electrodes 18, the separate gates 240, the gate electrodes 250, the wirings 250a drawn from the gate electrodes 250, and the wirings 260 may be formed of polycrystalline silicon. By adjusting the widths and lengths of the wirings 260 appropriately, the wirings 260 may be used as resistive elements. The wirings 260, when formed of polycrystalline silicon, may be used as polycrystalline silicon resistors.

During the operation of the semiconductor device 1C, each transistor element of the LDMOS transistors 10, nMOS transistors 200n, and pMOS transistors 200p generates heat. The heat generated by each transistor element is propagated through a relatively thin first part 51 of the first element isolation layer 50 to the first thermally conductive portions 40 and further to the second thermally conductive portions 80, and is then dissipated through the contacts 19 connected thereto. As a result, an increase in the temperature of the first semiconductor layer 30 due to the self-heating of each transistor element is suppressed, and a reduction in the driving capability of each transistor element caused by the temperature increase is suppressed accordingly.

In addition, in the semiconductor device 1C, the first thermally conductive portions 40, which surround each transistor element of the LDMOS transistors 10, nMOS transistors 200n, and pMOS transistors 200p in plan view and are connected with each other, are covered with the first element isolation layer 50. Therefore, in the semiconductor device 1C, a reduction in the layout flexibility for a variety of circuit elements that are provided on the first element isolation layer 50 is suppressed. In this example, the variety of circuit elements includes the gate electrodes 18, wirings 18a, separate gates 240, gate electrodes 250, wirings 250a, and wirings 260.

In this example, the gate electrodes 18, wirings 18a, separate gates 240, gate electrodes 250, wirings 250a, and wirings 260 are provided as circuit elements that are provided on the first element isolation layer 50. In addition to these, a variety of circuit elements may be provided on the first element isolation layer 50, such as a capacitor having a dielectric between a pair of electrodes or a part thereof, and an inductor with a conductor formed in a predetermined pattern shape or a part thereof, as well as a resistor formed using polycrystalline silicon or the like described above as an example or a part thereof. Even in the case where such circuit elements are provided, the reduction in the layout flexibility is suppressed, as in the case described above.

In the semiconductor device 1C as well, the first semiconductor layer 30 on which the transistor elements of the LDMOS transistors 10, nMOS transistors 200n, and pMOS transistors 200p are formed is surrounded by the insulating layer 20 and the first element isolation layer 50, which suppresses a decrease in the breakdown voltage.

This fourth embodiment also achieves the semiconductor device 1C that have high layout flexibility for circuit elements and suppresses performance degradation caused by the self-heating and a decrease in the breakdown voltage.

### Fifth Embodiment

The following describes an example of a method of manufacturing a semiconductor device as a fifth embodiment. Here, a method of manufacturing the semiconductor device 1 having the LDMOS transistor 10 as described above in the first embodiment will be described as an example.

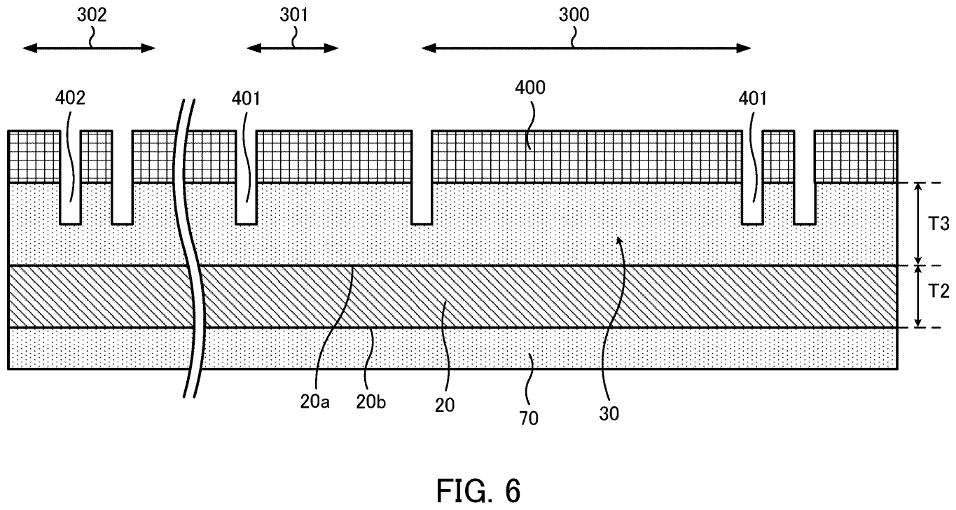

FIGS. 6 to 14 are views for describing an example of a semiconductor device manufacturing method according to the fifth embodiment. FIGS. 6 to 14 are schematic sectional views of a main part in each process for manufacturing the semiconductor device. The following describes the processes for manufacturing the semiconductor device one by one, with reference to FIGS. 6 to 14.

FIG. 6 is a view for describing an example of a first etching process.

First, an SOI substrate is prepared. FIG. 6 illustrates an SOI substrate in which the first semiconductor layer 30 (semiconductor material) is provided on the first surface 20a side of the insulating layer 20 (BOX layer) and the second semiconductor layer 70 (support substrate or semiconductor substrate) is provided on the second surface 20b side of the insulating layer 20. The insulating layer 20 is, for example, a silicon oxide layer with the thickness T2 of 300 nm (0.3 μm) to 600 nm (0.6 μm). The first semiconductor layer 30 is, for example, a silicon layer with a thickness T3 of 100 nm to 150 nm. The second semiconductor layer 70 is, for example, a silicon substrate.

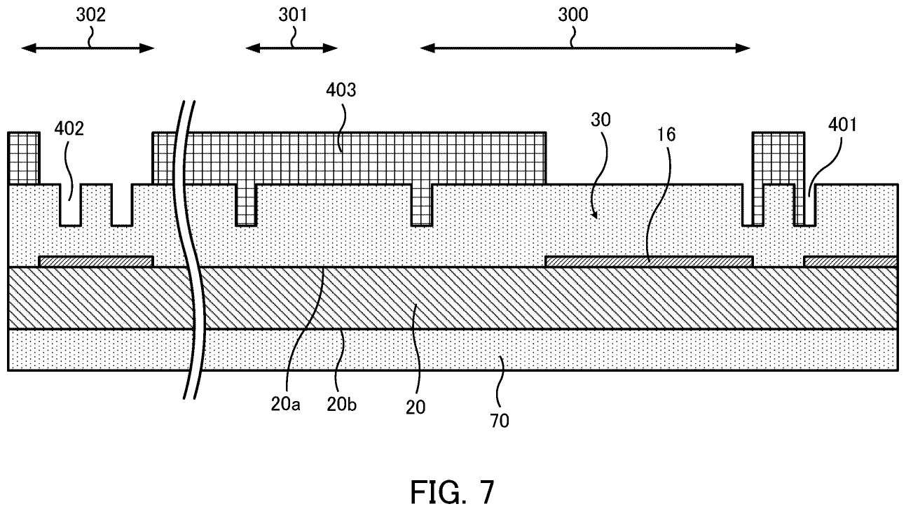

In FIG. 6, the insulating layer 20 is illustrated thinner than the first semiconductor layer 30 for convenience. However, the thickness relationship between the first semiconductor layer 30 and the insulating layer 20 is not limited to the illustrated one. The same holds true for the thickness relationship between the first semiconductor layer 30 and the insulating layer 20 in FIGS. 7 to 14 that will be described below.

On the front surface of the first semiconductor layer 30 of the SOI substrate, a silicon oxide film (not illustrated) with a thickness of 7 nm to 14 nm is formed by hydrochloric acid oxidation at a temperature of 900° C. to 1000° C. Then, a resist 400 is formed on the silicon oxide film as illustrated in FIG. 6. The resist 400 is formed by exposure using a mask having openings in predetermined regions and development after the exposure. Using the resist 400 as a mask, the silicon oxide film is anisotropically etched with a mixed gas of trifluoromethane (CHF₃) and tetrafluoromethane (CF₄). In addition, using the resist 400 and the etched silicon oxide film as masks, the first semiconductor layer 30 is anisotropically etched to a depth of about 50 nm to 70 nm with a chlorine (Cl₂)-based gas. As a result, a first trench 401 for defining the device region 300 and the heat sink region 301, and a second trench 402 serving as a mark for an alignment mark region 302 are formed, as illustrated in FIG. 6.

After the first trench 401 and the second trench 402 are formed, the resist 400 is removed by ashing. The silicon oxide film formed on the front surface of the first semiconductor layer 30 remains.

FIG. 7 is a view for describing an example of a deep well layer forming process.

A resist 403 is formed on the first semiconductor layer 30 (silicon oxide film remaining on the front surface thereof) etched as described above, as illustrated in FIG. 7. The resist 403 has an opening in a region where the deep well layer 16 is to be formed. The resist 403 is formed by photolithography using the second trench 402 formed in the alignment mark region 302 for alignment.

Using the formed resist 403 as a mask, an n-type impurity, for example, phosphorus (P) is ion-implanted to form an n-type deep well layer 16 at the bottom layer of the first semiconductor layer 30, as illustrated in FIG. 7. As an example, phosphorus is ion-implanted under the conditions of an acceleration energy of 1.5 MeV to 2.5 MeV, inclusive, and an implantation amount (dose) of 4.5×10¹² cm⁻² to 5.5×10¹² cm⁻², inclusive, to thereby form the n-type deep well layer 16.

After the deep well layer 16 is formed, the resist 403 is removed by ashing.

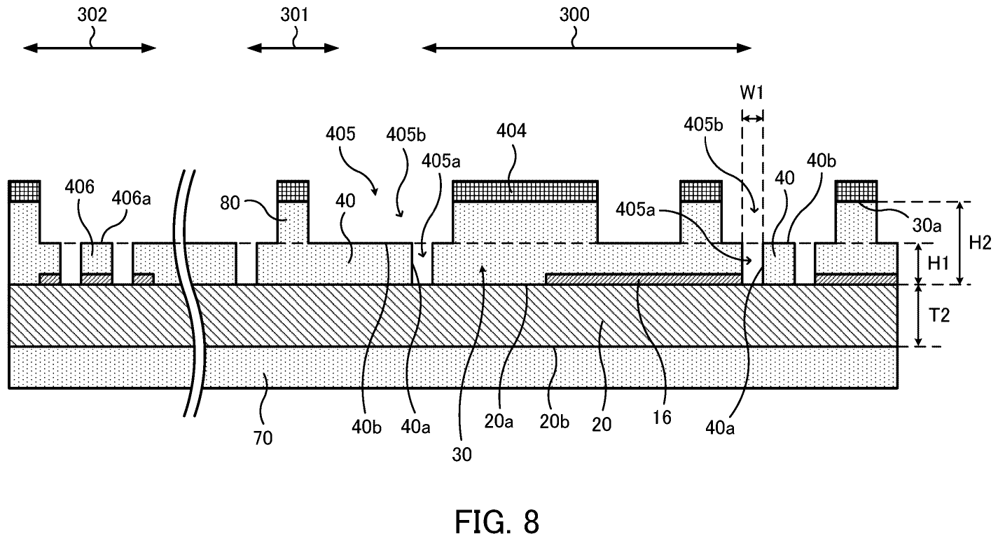

FIG. 8 is a view for describing an example of a second etching process.

After the deep well layer 16 is formed, a silicon oxide film (not illustrated) with a thickness of 7 nm to 14 nm is formed on the front surface of the first semiconductor layer 30 by hydrochloric acid oxidation at a temperature of 900° C. to 1000° C. Then, a silicon nitride film 404 with a thickness of 100 nm to 150 nm is formed on the silicon oxide film by the chemical vapor deposition (CVD) method, as illustrated in FIG. 8. After that, a resist (not illustrated) is formed on the silicon nitride film 404.

After that, the formed resist is exposed using a mask having an opening for forming an element isolation layer pattern and is then developed. Then, the silicon nitride film 404 and the silicon oxide film are anisotropically etched using the developed resist as a mask, with a mixed gas of trifluoromethane and tetrafluoromethane.

Then, the resist is removed by ashing. The first semiconductor layer 30 is selectively anisotropically etched using the silicon nitride film 404 remaining after the removal of the resist as a mask, with a chlorine-based gas until the insulating layer 20 is exposed. By doing so, a trench 405 that defines the first semiconductor layer 30 in the device region 300 is formed, and the first thermally conductive portion 40, which is provided in isolation from the first semiconductor layer 30, is formed in the trench 405, as illustrated in FIG. 8. In addition, the second thermally conductive portion 80 that is continuous with the first thermally conductive portion 40 is formed in the heat sink region 301. For example, the first thermally conductive portion 40 is formed to surround the entire periphery of the first semiconductor layer 30 in the device region 300 defined by the trench 405 in plan view, and the second thermally conductive portion 80 is formed to be continuous with a part of the first thermally conductive portion 40. In addition, an alignment mark 406 is formed in the alignment mark region 302.

The trench 405 includes a trench for forming the first element isolation layer 50, which will be described later, and a trench for forming the second element isolation layer 60, which will be described later.

The first thermally conductive portion 40 has the third surface 40a, which serves as a side surface facing the first semiconductor layer 30 in the device region 300, and the fourth surface 40b, which serves as an upper surface. The trench 405 includes a first isolating trench portion 405a the first semiconductor layer 30 in the device region 300 from the third surface 40a of the first thermally conductive portion 40. The trench 405 also includes a second trench portion 405b that is provided on the side of the first trench portion 405a opposite to the insulating layer 20 and that is continuous with the first trench portion 405a and extends further toward the first semiconductor layer 30 in the device region 300 than the first trench portion 405a.

The width between the first semiconductor layer 30 in the device region 300 and the third surface 40a of the first thermally conductive portion 40, that is, the width W1 of the first trench portion 405a (corresponding to the thickness T1 of the first part 51 of the first element isolation layer 50 to be described later) is set to a value ranging from 0.15 μm to 0.2 μm. The width W1 of the first trench portion 405a is set to a value smaller than the thickness T2 of the insulating layer 20 ranging from 0.3 μm (300 nm) to 0.6 μm (600 nm). The width of the first trench 401 described above in the process of FIG. 6 is adjusted so that the first trench portion 405a has such a width W1 through the etching.

The fourth surface 40b of the first thermally conductive portion 40 is located at the bottom of the second trench portion 405b. The height H1 of the bottom of the second trench portion 405b from the first surface 20a, i.e., the height H1 of the fourth surface 40b of the first thermally conductive portion 40 from the first surface 20a is lower than the height H2, from the first surface 20a, of the fifth surface 30a of the first semiconductor layer 30 located opposite to the insulating layer 20. The second trench portion 405b and the first thermally conductive portion 40 are formed by etching so as to obtain such a height H1.

In this connection, the bottom of the second trench portion 405b of the trench 405 serves as the sixth surface 50a of the second part 52 of the first element isolation layer 50, which will be described later. The bottom of the trench 405 that is not continuous with the first trench portion 405a serves as the seventh surface 60a of the second element isolation layer 60, which will be described later.

The alignment mark 406 has an eighth surface 406a that serves as its upper surface. The eighth surface 406a is located at the bottom of the second trench portion 405b. For example, the height of the eighth surface 406a from the first surface 20a is equal to the height H1 of the bottom of the second trench portion 405b from the first surface 20a, that is, the height H1 of the fourth surface 40b of the first thermally conductive portion 40 from the first surface 20a. For example, the second trench portion 405b, the first thermally conductive portion 40, and the alignment mark 406 are formed by etching so as to obtain such a height H1.

In this connection, not limited to the above example, the trench 405 does not necessarily have to be formed such that the heights of the fourth surface 40b of the first thermally conductive portion 40 and the eighth surface 406a of the alignment mark 406 with respect to the first surface 20a of the insulating layer 20 match each other.

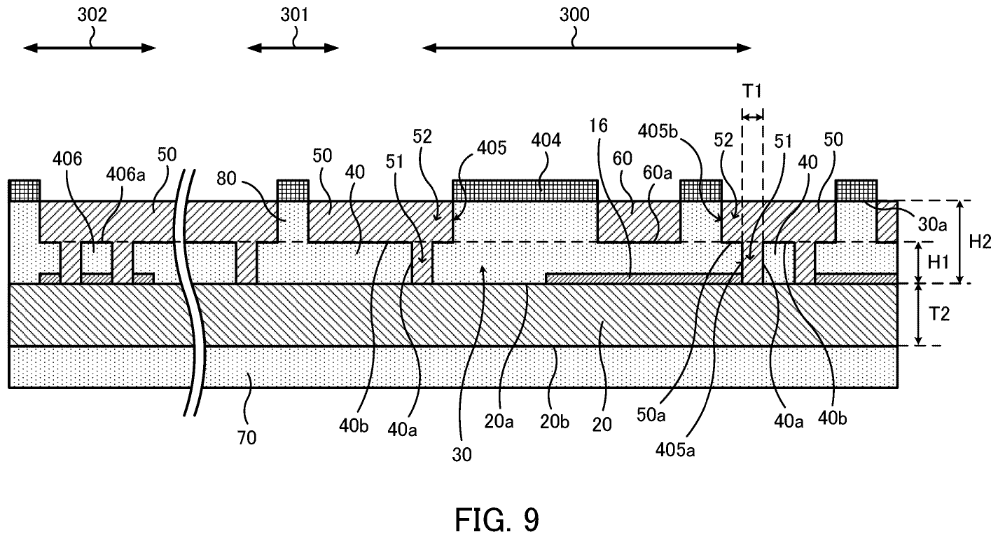

FIG. 9 is a view for describing an example of an element isolation layer forming process.

A silicon oxide film (not illustrated) with a thickness of 7 nm to 14 nm is formed on the front surface of the first semiconductor layer 30 etched as described above, by thermal oxidation at a temperature of 1050° C. to 1150° C. Then, a silicon oxide film with a thickness of 250 nm to 400 nm is further formed on the silicon oxide film by the CVD method to fill the trench 405. The silicon oxide film filling the trench 405 is polished until the silicon nitride film 404 is exposed. As a result, the first element isolation layer 50 and the second element isolation layer 60 as illustrated in FIG. 9 are formed.

The formed first element isolation layer 50 fills the first and second trench portions 405a and 405b of the trench 405 and covers the third surface 40a and fourth surface 40b of the first thermally conductive portion 40. The first part 51 of the first element isolation layer 50 is formed in the first trench portion 405a, and the second part 52 of the first element isolation layer 50 is formed in the second trench portion 405b. The thickness T1 (corresponding to the width W1 of the above-described first trench portion 405a) of the first part 51 of the first element isolation layer 50 is less than the thickness T2 of the insulating layer 20. The bottom of the second part 52 of the first element isolation layer 50 serves as the sixth surface 50a of the first element isolation layer 50. The bottom of the second element isolation layer 60 serves as the seventh surface 60a of the second element isolation layer 60. A part of the first semiconductor layer 30 is interposed between each of the sixth and seventh surfaces 50a and 60a and the first surface 20a and is in contact with the sixth surface 50a and the seventh surface 60a.

For example, the heights of the sixth surface 50a of the first element isolation layer 50 and the seventh surface 60a of the second element isolation layer 60 from the first surface 20a of the insulating layer 20 are equal to the height H1 of the fourth surface 40b of the first thermally conductive portion 40 from the first surface 20a. For example, in the above-described process of FIG. 8, the trench 405 is formed by etching so as to form the first element isolation layer 50 having such a sixth surface 50a and the second element isolation layer 60 having such a seventh surface 60a.

After the first element isolation layer 50 and the second element isolation layer 60 are formed, the silicon nitride film 404 is removed with a boiling phosphoric acid solution.

In this connection, not limited to the above example, the first thermally conductive portion 40, the first element isolation layer 50, and the second element isolation layer 60 do not necessarily have to satisfy the condition that the heights of the fourth surface 40b, sixth surface 50a, and seventh surface 60a with respect to the first surface 20a of the insulating layer 20 match each other. In other words, not limited to the above example, the trench 405 does not necessarily have to be formed such that the heights of the fourth surface 40b, sixth surface 50a, and seventh surface 60a with respect to the first surface 20a of the insulating layer 20 match each other.

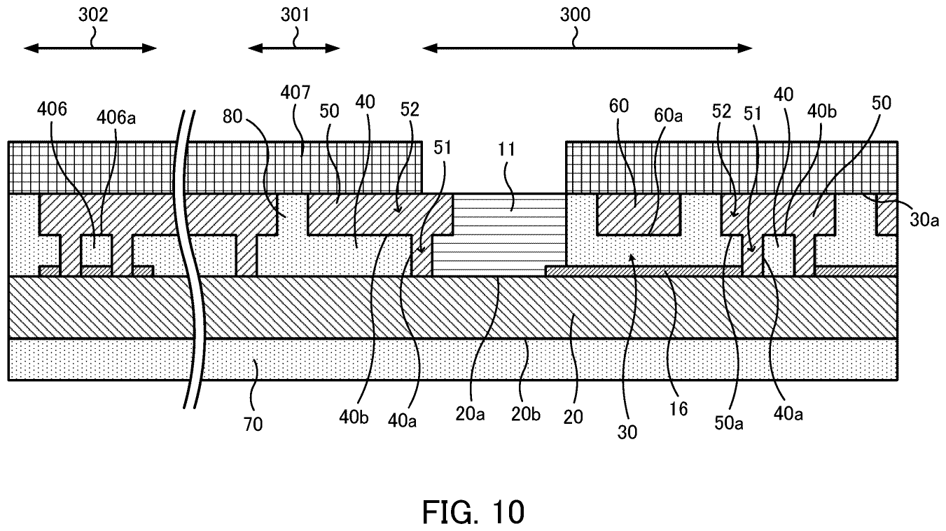

FIG. 10 is a view for describing an example of a body region forming process.

After the first element isolation layer 50 and the second element isolation layer 60 are formed and the silicon nitride film 404 is removed, a resist 407 having an opening in the region where the body region 11 of the first semiconductor layer 30 is to be formed is formed, as illustrated in FIG. 10.

A p-type impurity, for example, boron (B) is ion-implanted using the formed resist 407 as a mask, to form the p-type body region 11 in the first semiconductor layer 30, as illustrated in FIG. 10. As an example, boron is ion-implanted under the conditions of an acceleration energy of 100 keV to 200 keV, inclusive, and an implantation amount of 1.0×10¹² cm⁻² to 3.0×10¹³ cm⁻², inclusive, to thereby form the p-type body region 11.

A p-type impurity may be further ion-implanted into the body region 11 for controlling the threshold voltage of the transistor. As an example, for the threshold voltage control, boron is ion-implanted with the conditions of an acceleration energy of 5 keV to 30 keV, inclusive, and an implantation amount of 9.5×10¹² cm⁻² to 1.05×10¹³ cm⁻², inclusive.

After the body region 11 is formed, the resist 407 is removed by ashing.

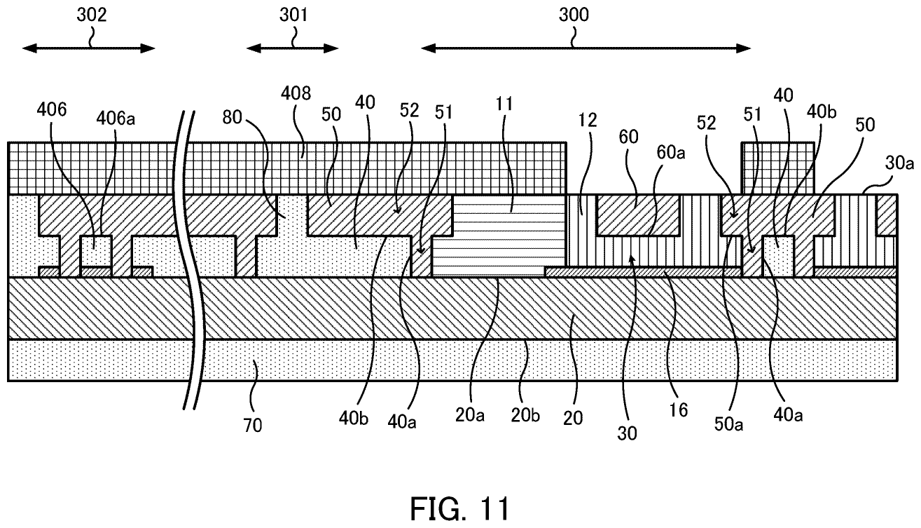

FIG. 11 is a view for describing an example of a drift region forming process.

After the body region 11 is formed, a resist 408 having an opening in the region where the drift region 12 of the first semiconductor layer 30 is to be formed is formed, as illustrated in FIG. 11.

An n-type impurity, for example, phosphorus, arsenic (As), or the like is ion-implanted using the resist 408 as a mask, to form the n-type drift region 12 in the first semiconductor layer 30, as illustrated in FIG. 11. As an example, phosphorus is ion-implanted under the conditions of an acceleration energy of 0.5 MeV to 1.0 MeV, inclusive, and an implantation amount of 4.5×10¹² cm⁻² to 5.5×10¹² cm⁻², inclusive, to thereby form the n-type drift region 12.

After the drift region 12 is formed, the resist 408 is removed by ashing.

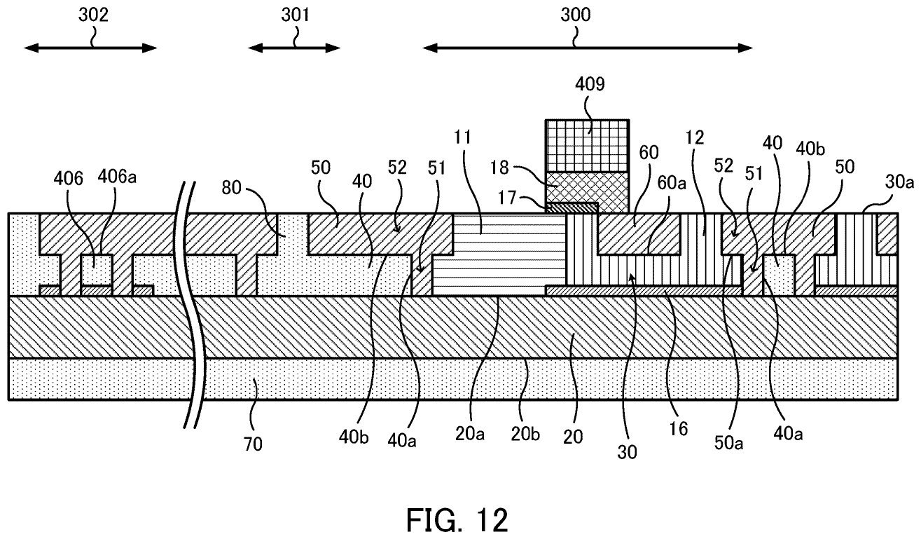

FIG. 12 is a view for describing an example of a gate electrode forming process.

After the drift region 12 is formed, the silicon oxide film is removed by wet etching using a hydrofluoric acid. After that, the gate insulating film 17 is formed on the exposed surface of the first semiconductor layer 30 (body region 11 and drift region 12) in the device region 300 by a thermal oxidation method, as illustrated in FIG. 12. The thickness of the gate insulating film 17 is between 12 nm and 25 nm, inclusive, for example.

After the gate insulating film 17 is formed, a polysilicon film is deposited by the CVD method. The thickness of the polysilicon film is between 100 nm and 200 nm, inclusive, for example. After the polysilicon film is formed, a resist 409 is formed on the polysilicon film by photolithography, and the polysilicon film is patterned by dry etching using the resist 409 as a mask. As a result, the gate electrode 18 is formed.

The gate electrode 18 is formed to overlap the first semiconductor layer 30 and the second element isolation layer 60 in plan view. In addition, the gate electrode 18 is formed to overlap the first thermally conductive portion 40 in plan view, for example, as illustrated in FIG. 1.

After the gate electrode 18 is formed, the resist 409 is removed by ashing.

In this connection, in addition to the gate electrode 18, a wiring that is connected thereto or separated therefrom may be formed on the first element isolation layer 50. Alternatively, a resistor or a part thereof, a capacitor or a part thereof, and/or an inductor or a part thereof may be formed on the first element isolation layer 50. A variety of circuit elements such as the gate electrode 18 or another gate electrode, a wiring, a resistor, a capacitor, and an inductor may be formed to overlap the first thermally conductive portion 40 in plan view.

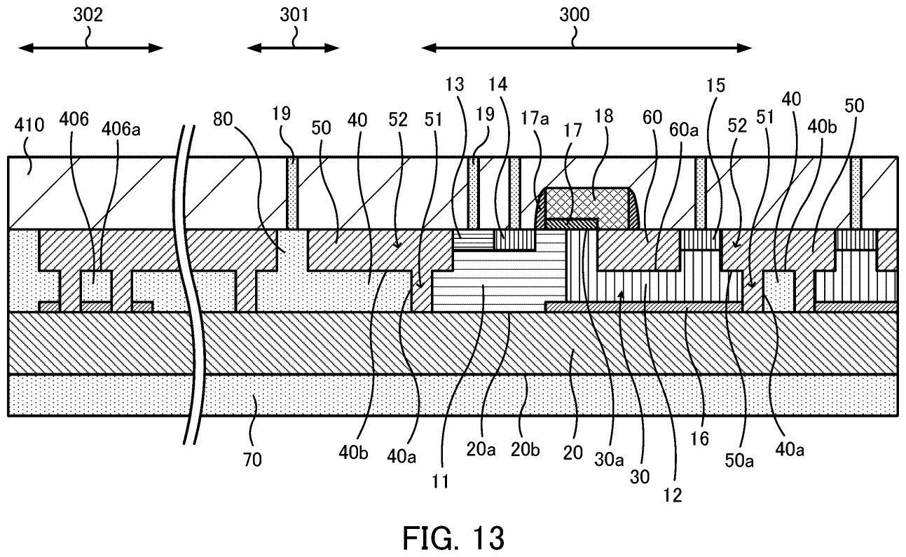

FIG. 13 is a view for describing an example of an impurity region and contact forming process.

After the gate electrode 18 is formed, the sidewall insulating film 17a is formed on the sidewall of the gate electrode 18 by, for example, a silicon oxide film or the like, as illustrated in FIG. 13.

Then, an n-type impurity, for example, phosphorus, arsenic, or the like is ion-implanted into the first semiconductor layer 30 in the device region 300 to form the n-type source region 14 in the surface layer of the body region 11 and the drain region 15 in the surface layer of the drift region 12, as illustrated in FIG. 13. As an example, phosphorus is ion-implanted under the conditions of an acceleration energy of 12 keV to 18 keV, inclusive, and an implantation amount of 2.0×10¹⁵ cm⁻² to 6.0×10¹⁵ cm⁻², inclusive, to thereby form the n-type source region 14 and drain region 15.

In addition, a p-type impurity, for example, boron or the like is further ion-implanted into the surface layer of the body region 11 to form the p-type body contact region 13, as illustrated in FIG. 13. As an example, boron is ion-implanted under the conditions of an acceleration energy of 4 keV to 10 keV, inclusive, and an implantation amount of 1.0×10¹⁵ cm⁻² to 4.0×10¹⁵ cm⁻², inclusive, to thereby form the p-type body contact region 13.

After the ion implantation, heat treatment is performed in an inert gas atmosphere to activate the impurities implanted into the body contact region 13, source region 14, and drain region 15.

For example, a metal silicide layer (not illustrated) is formed on the surface layers of the body contact region 13, source region 14, and drain region 15.

After the body contact region 13, the source region 14, and the drain region 15 are formed, an interlayer dielectric film 410 is deposited as illustrated in FIG. 13. Then, openings are formed in the interlayer dielectric film 410 to be continuous at predetermined locations with the body contact region 13, source region 14, drain region 15, gate electrode 18 (not illustrated), and second thermally conductive portion 80, and the openings are filled with an electrically conductive material such as tungsten to form the contacts 19 as illustrated in FIG. 13.

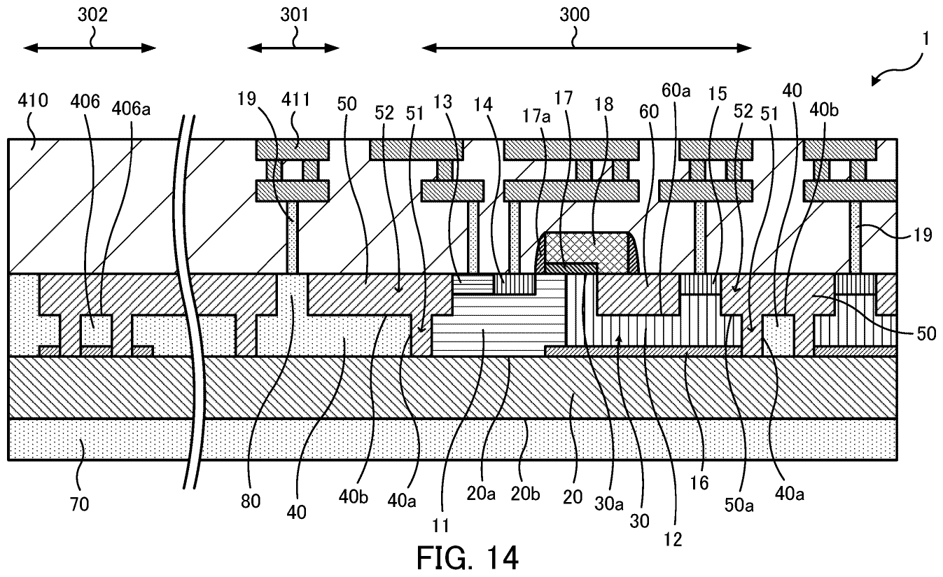

FIG. 14 is a view for describing an example of a wiring layer forming process.

After the body contact region 13, source region 14 drain region 15, and then the interlayer dielectric film 410 and contacts 19 are formed, the interlayer dielectric film 410 is further deposited, as illustrated in FIG. 14. Then, a wiring layer 411 is formed using an electrically conductive material such as copper (Cu) in the interlayer dielectric film 410, for example, by the damascene method. The wiring layer 411 is connected to the contacts 19 formed in the device region 300 and the heat sink region 301.

Through the processes described above, the semiconductor device 1 with the n-type LDMOS transistor 10 is manufactured.

The above description has described the method of manufacturing the semiconductor device 1 with the n-type LDMOS transistor 10, as an example. Alternatively, a semiconductor device 1 with a p-type LDMOS transistor 10 may be similarly manufactured by swapping the p-type impurity and the n-type impurity in the above example.

As described earlier, in the semiconductor device 1, the heat generated by the LDMOS transistor 10 in the device region 300 is easily propagated to the first thermally conductive portion 40 through the first part 51 of the first element isolation layer 50, which is relatively thin compared to the insulating layer 20. The heat propagated to the first thermally conductive portion 40 is dissipated through the second thermally conductive portion 80 continuous with the first thermally conductive portion 40 in the heat sink region 301, and also through the contacts 19 and the wiring layer 411 connected thereto. This suppresses a reduction in the driving capability caused by the self-heating of the LDMOS transistor 10.

In addition, in the semiconductor device 1, the LDMOS transistor 10 is surrounded by the insulating layer 20 and the first element isolation layer 50, and the insulating layer 20 may be made relatively thick, which suppresses a decrease in the breakdown voltage.

Furthermore, the first thermally conductive portion 40 is covered with the first element isolation layer 50, which suppresses a reduction in the layout flexibility for a variety of circuit elements to be provided on the first element isolation layer 50. With the above-described manufacturing method, the semiconductor device 1 is achieved, which has high layout flexibility for circuit elements and suppresses performance degradation caused by the self-heating and a decrease in the breakdown voltage.

The method of manufacturing the semiconductor device 1 described above in the first embodiment has been described as an example. Alternatively, it is also possible to employ the example as described in the fifth embodiment to manufacture the semiconductor device 1A (FIG. 3) that has the MOS transistor 10A instead of the LDMOS transistor 10 as described above in the second embodiment. It is also possible to employ the example as described in the fifth embodiment to manufacture the semiconductor device 1B (FIG. 4) that has the first thermally conductive portion 40 that does not surround the entire periphery of the first semiconductor layer 30 in plan view as described above in the third embodiment. It is also possible to employ the example as described in the fifth embodiment to manufacture the semiconductor device 1C in which the LDMOS transistors 10 and the CMOS transistors 200 are integrated as described above in the fourth embodiment.

In one aspect, it is possible to achieve a semiconductor device that has high layout flexibility for circuit elements and suppresses performance degradation caused by self-heating and a decrease in breakdown voltage.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
an insulating layer having a first surface on a first side thereof and a second surface on a second side thereof opposite to the first side;
a first semiconductor layer provided on the first side of the insulating layer;
a first thermally conductive portion provided in isolation from the first semiconductor layer on the first side of the insulating layer, the first thermally conductive portion having a third surface and a fourth surface, the third surface facing the first semiconductor layer in a first direction parallel to the first surface, the fourth surface facing a second direction that is orthogonal to the first direction and is directed away from the first surface; and
a first element isolation layer provided on the first side of the insulating layer to define the first semiconductor layer and to cover the third surface and the fourth surface of the first thermally conductive portion;
wherein a thickness of a first part of the first element isolation layer located between the first semiconductor layer and the third surface is less than a thickness of the insulating layer between the first surface and the second surface.

2. The semiconductor device according to claim 1, wherein the first thermally conductive portion surrounds an entire periphery of the first semiconductor layer in a plan view of the semiconductor device.

3. The semiconductor device according to claim 1, wherein a height of the fourth surface from the first surface is lower than a height, from the first surface, of a fifth surface of the first semiconductor layer located opposite to the insulating layer.

4. The semiconductor device according to claim 1, further comprising a second thermally conductive portion provided in the first element isolation layer, the second thermally conductive portion being continuous with the first thermally conductive portion and having a part extending outside the first element isolation layer.

5. The semiconductor device according to claim 1, further comprising a second semiconductor layer provided on the second side of the insulating layer.

6. The semiconductor device according to claim 5, wherein the second semiconductor layer is connected to an earth potential.

7. The semiconductor device according to claim 1, wherein the first thermally conductive portion is electrically floating.

8. The semiconductor device according to claim 1, wherein the first thermally conductive portion is in contact with the first surface.

9. The semiconductor device according to claim 1, wherein the first thermally conductive portion and the first semiconductor layer have respective surfaces facing toward the insulating layer, and the respective surfaces are in a same plane parallel to the first surface.

10. The semiconductor device according to claim 1, wherein a same semiconductor material is used for both the first semiconductor layer and the first thermally conductive portion.

11. The semiconductor device according to claim 1, wherein:
the first element isolation layer includes a second part extending further toward the first semiconductor layer than the first part, the second part having a sixth surface that faces toward the insulating layer and is located apart from the first surface; and
a part of the first semiconductor layer is interposed between the sixth surface and the first surface and is in contact with the sixth surface.

12. The semiconductor device according to claim 11, wherein a height of the sixth surface from the first surface is equal to a height of the fourth surface from the first surface.

13. The semiconductor device according to claim 1, further comprising a second element isolation layer provided in the first semiconductor layer, the second element isolation layer having a seventh surface that faces toward the insulating layer and is located apart from the first surface, wherein a part of the first semiconductor layer is interposed between the seventh surface and the first surface and is in contact with the seventh surface.

14. The semiconductor device according to claim 13, wherein a height of the seventh surface from the first surface is equal to a height of the fourth surface from the first surface.

15. The semiconductor device according to claim 13, further comprising a gate electrode provided on a side of the first semiconductor layer opposite to the insulating layer so as to overlap the first semiconductor layer and the second element isolation layer in a plan view of the semiconductor device.

16. The semiconductor device according to claim 1, further comprising a circuit element provided on a side of the first element isolation layer opposite to the insulating layer so as to overlap the first thermally conductive portion in a plan view of the semiconductor device.

17. The semiconductor device according to claim 16, wherein the circuit element is at least one of an electrode, a wiring, a resistor, a capacitor, or an inductor.

18. The semiconductor device according to claim 1, further comprising an alignment mark provided on the first side of the insulating layer, the alignment mark having an eighth surface,
wherein a height of the eighth surface from the first surface is equal to a height of the fourth surface from the first surface.

19. A semiconductor device manufacturing method, comprising:
forming a first semiconductor layer on a first side of an insulating layer having a first surface on the first side thereof and a second surface on a second side thereof opposite to the first side;
forming a first thermally conductive portion in isolation from the first semiconductor layer on the first side of the insulating layer, the first thermally conductive portion having a third surface and a fourth surface, the third surface facing the first semiconductor layer in a first direction parallel to the first surface, the fourth surface facing a second direction that is orthogonal to the first direction and is directed away from the first surface; and
forming a first element isolation layer on the first side of the insulating layer to define the first semiconductor layer and to cover the third surface and the fourth surface of the first thermally conductive portion;
wherein a thickness of a first part of the first element isolation layer located between the first semiconductor layer and the third surface is less than a thickness of the insulating layer between the first surface and the second surface.

20. The semiconductor device manufacturing method according to claim 19, wherein the forming of the first thermally conductive portion includes forming the first thermally conductive portion so as to surround an entire periphery of the first semiconductor layer in a plan view.

21. The semiconductor device manufacturing method according to claim 19, wherein:
the forming of the first thermally conductive portion includes
forming a trench to define the first semiconductor layer by etching a semiconductor material provided on the first side of the insulating layer, and
forming, in the trench, the first thermally conductive portion in isolation from the first semiconductor layer, and
the forming of the first element isolation layer includes forming, in the trench, the first element isolation layer to cover the first thermally conductive portion.

22. The semiconductor device manufacturing method according to claim 21, wherein the forming of the first thermally conductive portion in the trench includes forming the first thermally conductive portion such that a height of the fourth surface from the first surface is lower than a height, from the first surface, of a fifth surface of the first semiconductor layer located opposite to the insulating layer.

23. The semiconductor device manufacturing method according to claim 21, wherein:
the forming of the trench includes
forming a first trench portion isolating the first semiconductor layer form the third surface, and
forming a second trench portion on a side of the first trench portion opposite to the insulating layer such that the second trench portion is continuous with the first trench portion and extends further toward the first semiconductor layer than the first trench portion, and
the forming of the first element isolation layer includes:
forming the first part in the first trench portion, and
forming a second part in the second trench portion such that the second part has a sixth surface facing toward the insulating layer and being located apart from the first surface, and a part of the first semiconductor layer is interposed between the sixth surface and the first surface and is in contact with the sixth surface.

24. The semiconductor device manufacturing method according to claim 19, further comprising forming a second thermally conductive portion in the first element isolation layer such that the second thermally conductive portion is continuous with the first thermally conductive portion and has a part extending outside the first element isolation layer.

25. The semiconductor device manufacturing method according to claim 19, further comprising forming a second element isolation layer in the first semiconductor layer such that the second element isolation layer has a seventh surface facing toward the insulating layer and being located apart from the first surface, and a part of the first semiconductor layer is interposed between the seventh surface and the first surface and is in contact with the seventh surface.

26. The semiconductor device manufacturing method according to claim 25, further comprising forming a gate electrode on a side of the first semiconductor layer opposite to the insulating layer such that the gate electrode overlaps the first semiconductor layer and the second element isolation layer in a plan view.

27. The semiconductor device manufacturing method according to claim 19, further comprising forming a circuit element on a side of the first element isolation layer opposite to the insulating layer such that the circuit element overlaps the first thermally conductive portion in a plan view.

28. The semiconductor device manufacturing method according to claim 27, wherein the circuit element is at least one of an electrode, a wiring, a resistor, a capacitor, or an inductor.

29. The semiconductor device manufacturing method according to claim 19, further comprising forming an alignment mark on the first side of the insulating layer such that the alignment mark has an eighth surface and a height of the eighth surface from the first surface is equal to a height of the fourth surface from the first surface.
